(19) United States
(12) Patent Application Publication
(10) Pub. No.: US 2016/0269011 A1
(43) Pub. Date: Sep. 15, 2016

(54) CIRCUIT DEVICE, ELECTRONIC APPARATUS, AND MOVING OBJECT

(71) Applicant: Seiko Epson Corporation, Tokyo (JP)

(72) Inventors: Jun UEHARA, Fujimi (JP); Takashi AOYAMA, Chino (JP)

(21) Appl. No.: 15/066,054

(22) Filed: Mar. 10, 2016

(30) Foreign Application Priority Data
Mar. 13, 2015 (JP) 2015-050550

(51) Int. Cl. H03K 5/15; G01P 15/09; G01P 15/125; H03K 17/00; G01C 19/5705

(52) U.S. Cl. CPC H03K 5/15013; H03K 17/005; G01C 19/5705; G01P 15/125; G01P 15/09

(57) ABSTRACT

A circuit device includes a multiplexer that selects an input signal from first to n-th input signals in a time division manner and outputs the selected input signal to an output node, an A/D conversion circuit that receives the first to n-th input signals outputted from the multiplexer to the output node in a time division manner and A/D-converts the received first to n-th input signals in a time division manner, and a buffer circuit provided between an i-th input node and the output node of the multiplexer. The buffer circuit buffers the i-th input signal and outputs the buffered signal to the output node of the multiplexer in a first period. The multiplexer selects the i-th input signal and outputs the selected signal to the output node in a second period. End timing of the second period comes after end timing of the first period.

### BACKGROUND

1. Technical Field

The present invention relates to a circuit device, an electronic apparatus, a moving object, and the like.

2. Related Art

In recent years, a gyro sensor, an acceleration sensor, and other motion sensors have come into the spotlight. Use of such a motion sensor, for example, achieves hand-shake blur correction in a camera and intuitive operation input in a game console. An example of related art technology for an apparatus that receives a detection signal from such a sensor device and performs A/D conversion and filtering is a technology disclosed in JP-A-2012-42261. In JP-A-2012-42261, detection signals from sensor devices are A/D-converted in a time division manner, and a multiplexer selects a detection signal to be inputted to an A/D conversion circuit from the detection signals in a time division manner.

When the multiplexer selects an input signal from a plurality of input signals in a time division manner, an input to the A/D conversion circuit changes in a time division manner. The A/D conversion circuit samples the input signal, and the input to the A/D conversion circuit (output from multiplexer) therefore needs to be determined by the sampling timing. In this process, the sampling frequency of the A/D conversion is the product of the frequency at which each input signal is sampled and the number of time division sampling operations performed by the multiplexer and is therefore higher than in a case where a single input signal is A/D-converted.

When a circuit in a stage upstream of the multiplexer has poor driving capability, however, the output of the multiplexer is not sufficiently driven when the input signal is selected. The output of the multiplexer therefore does not reach the level of the input signal by the time when the A/D conversion sampling is performed, and an accurate A/D-converted value is undesirably produced. A gyro sensor and an acceleration sensor, for example, each use a low-pass filter for band limitation, and it is desirable to use a passive low-pass filter from a viewpoint of the S/N ratio. For example, when the time constant of a passive low-pass filter is longer than the sampling cycle of the A/D conversion, the output of the multiplexer is likely not to reach the level of an input signal by the time when the A/D conversion sampling is performed.

### SUMMARY

An advantage of some aspects of the invention is to provide a circuit device, an electronic apparatus, and a moving object capable of producing an accurate A/D-converted value even when a circuit in a stage upstream of a multiplexer has poor driving capability.

An aspect of the invention relates to a circuit device including a multiplexer that selects an input signal from first to n-th input signals (n is an integer greater than or equal to 2) inputted to first to n-th nodes in a time division manner and outputs the selected input signal to an output node, an A/D conversion circuit that receives the first to n-th input signals outputted from the multiplexer to the output node in a time division manner and A/D-converts the received first to n-th input signals in a time division manner, and a buffer circuit provided between an i-th input node (i is an integer greater than or equal to 1 but smaller than or equal to n) among the first to n-th input nodes and the output node of the multiplexer. The buffer circuit buffers the i-th input signal among the first to n-th input signals and outputs the buffered signal to the output node of the multiplexer in a first period. The multiplexer selects the i-th input signal and outputs the selected signal to the output node in a second period. End timing of the second period comes after end timing of the first period.

According to the aspect of the invention, the buffer circuit buffers the i-th input signal inputted to the i-th input node of the multiplexer and outputs the buffered signal to the output node of the multiplexer in the first period, and the multiplexer selects the i-th input signal and outputs the selected signal to the output node of the multiplexer in the second period. In this process, the second period ends after the first period ends. As a result, even when the stage upstream of the multiplexer has poor driving capability, the buffer circuit buffers the i-th input signal, whereby an accurate A/D-converted value can be produced.

In the aspect of the invention, the A/D conversion circuit may sample the i-th input signal after the end timing of the first period but before the end timing of the second period.

The A/D conversion circuit, which samples the i-th input signal after the end timing of the first period, can perform the sampling after the buffer circuit performs the buffering. The buffer circuit can therefore perform the buffering without 1/f noise produced by an active circuit and other adverse effects.

In the aspect of the invention, start timing of the second period may come after start timing of the first period.

If the start timing of the second period comes before the start timing of the first period, the multiplexer selects the i-th input signal before the buffer circuit performs the buffering. At this point, the output from the multiplexer is an (i−1)-th input signal. When the stage upstream of the multiplexer has poor driving capability, the output from the multiplexer ((i−1)-th input signal) undesirably affects and changes the i-th input signal to the multiplexer. In this regard, according to the aspect of the invention, in which the start timing of the second period comes after the start timing of the first period, the buffer circuit can perform the buffering before the i-th input signal is selected and output the i-th input signal to the output node of the multiplexer.

In the aspect of the invention, the buffer circuit may include an amplifier circuit that amplifies the i-th input signal and a switch element provided between an output of the amplifier circuit and the output node, and the switch element may be turned on in the first period.

In this configuration, in the first period, where the switch element is turned on, the amplifier circuit can buffer the i-th input signal and output the buffered signal to the output node of the multiplexer. Further, since the switch element is turned off, the output of the amplifier circuit can be isolated from the output node of the multiplexer. The i-th input signal can therefore be A/D-converted without any influence of noise produced by the amplifier circuit.

In the aspect of the invention, the circuit device may further include a second buffer circuit provided between an (i+1)-th input node (i is smaller than or equal to n−1) among the first to n-th input nodes and the output node of the multiplexer. The second buffer circuit may buffer an (i+1)-th input signal among the first to n-th input signals and output the buffered signal to the output node in a third period. The multiplexer may select the (i+1)-th input signal and output the selected signal to the output node in a fourth period. End timing of the fourth period may be set at a point after end timing of the third period.

In the aspect of the invention, start timing of the third period may be set at a point after the end timing of the second period.

If the (i+1)-th input signal is buffered at the output node of the multiplexer when the multiplexer is selecting the i-th input signal, the i-th input signal undesirably changes. In this regard, according to the aspect of the invention, the start timing of the third period is set at a point after the end timing of the second period. The (i+1)-th input signal is therefore not buffered at the output node of the multiplexer when the multiplexer is selecting the i-th input signal.

In the aspect of the invention, the circuit device may further include a passive low-pass filter, and the i-th input signal may be an output signal from the passive low-pass filter.

When the cutoff frequency of the passive low-pass filter is lower than the frequency of the time division operation performed by the multiplexer, a state in which the stage upstream of the multiplexer has poor driving capability occurs, and an accurate A/D-converted value cannot be produced. In this regard, according to the aspect of the invention, the buffer circuit can compensate for the driving capability, whereby an accurate A/D-converted value can be produced.

In the aspect of the invention, the circuit device may further include a detection circuit to which a detection signal from a physical quantity transducer is inputted, and the i-th input signal may be an output signal outputted by the detection circuit and inputted via the passive low-pass filter.

A low-pass filter is required to remove noise produced by the detection circuit. If an active low-pass filter is used, noise produced by the active low-pass filter is undesirably inputted to the A/D conversion circuit. In this regard, according to the aspect of the invention, the passive low-pass filter, which is a passive circuit, does not form a noise source. Further, in the aspect of the invention, the buffer circuit can compensate for the driving capability.

In the aspect of the invention, the physical quantity transducer may be an angular velocity sensor.

In the aspect of the invention, the physical quantity transducer may be an acceleration sensor.

When an angular velocity sensor is used, a low-pass filter is required, for example, to smoothen a detection signal and remove a detuning frequency component. When an acceleration sensor is used, a low-pass filter is required, for example, for anti-aliasing. According to the aspect of the invention, use of the passive low-pass filter can prevent a decrease in S/N ratio, and provision of the buffer circuit allows generation of an accurate A/D-converted value.

In the aspect of the invention, the i-th input signal may be formed of differential signals, and the output node may be formed of differential nodes. The A/D conversion circuit may A/D-convert the i-th input signal outputted to the differential nodes.

The configuration described above allows the multiplexer to select differential signals in a time division manner, and the differential signals can be A/D-converted. As a result, differential analog processing in a stage upstream of the multiplexer and differential A/D conversion can be performed, whereby advantages, such as improvement in the S/N ratio, reduction in in-phase noise, and other types of benefit of differential processing, can be provided.

In the aspect of the invention, the detection circuit may include a synchronization detection circuit.

According to the aspect of the invention, the passive low-pass filter can smoothen the output from the synchronization detection circuit. Provision of the passive low-pass filter lowers the driving capability in the stage upstream of the multiplexer, but provision of the buffer circuit allows generation of an accurate A/D-converted value.

In the aspect of the invention, the detection circuit may include an amplification circuit provided in a stage upstream of the synchronization detection circuit and an electric charge/voltage conversion circuit provided in a stage upstream of the amplification circuit.

In this configuration, when a physical quantity transducer that outputs a current signal as the detection signal is used, a desired signal can be detected from the current signal.

Another aspect of the invention relates to an electronic apparatus including any of the circuit devices described above.

Still another aspect of the invention relates to a moving object including any of the circuit devices described above.

### BRIEF DESCRIPTION OF THE DRAWINGS

The invention will be described with reference to the accompanying drawings, wherein like numbers reference like elements.

FIG. 1 shows a first configuration example of a circuit device.

FIG. 2 shows a second configuration example of the circuit device.

FIG. 3 shows an example of detailed configurations of a buffer circuit and a sensor.

FIG. 4 is a timing chart in accordance with which the buffer circuit and a multiplexer operate.

FIG. 5 is a timing chart in accordance with which the buffer circuit, the multiplexer, and an A/D conversion circuit operate.

FIG. 6 shows a simulation result in an embodiment of the invention.

FIG. 7 shows another simulation result in the present embodiment.

FIG. 8 shows an example of the sensor configuration in a case where a first physical quantity transducer is a vibrator element.

FIG. 9 shows an example of a detailed configuration of a detection circuit.

FIG. 10 shows an example of a basic configuration of the A/D conversion circuit.

FIG. 11 shows an example of detailed configurations of an S/H circuit, a D/A conversion circuit, and a comparison circuit.

FIG. 12 is a timing chart in accordance with which the A/D conversion circuit operates.

FIG. 13 shows an example of the configuration of an electronic apparatus.

FIGS. 14A to 14D show examples of a moving object and an electronic apparatus.

### DESCRIPTION OF EXEMPLARY EMBODIMENTS

Preferable embodiments of the invention will be described below in detail. It is not intended that the embodiments described below unduly limit the contents of the invention set forth in the appended claims, and all configurations described in the embodiments are not necessarily essential as solutions provided by the invention.

### 1. First Configuration Example

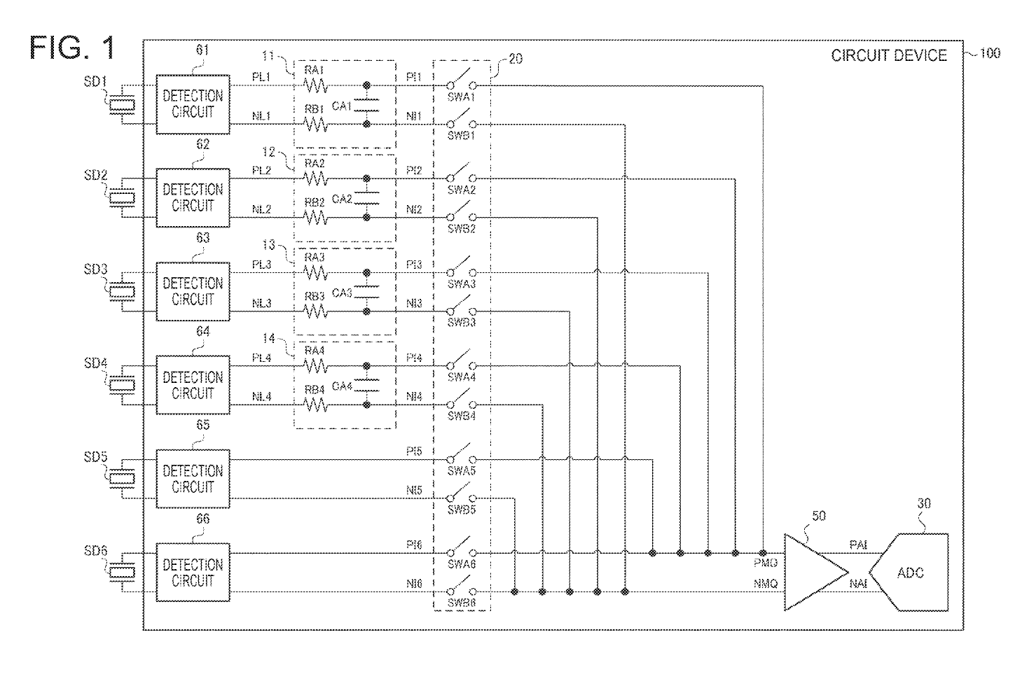

FIG. 1 shows a first configuration example of a sensor and a circuit device. The sensor of the first configuration example includes physical quantity transducers SD1 to SD6 (first to n-th physical quantity transducers, where n is an integer greater than or equal to 2) and a circuit device (detection device) that receives detection signals from the physical quantity transducers SD1 to SD6 and detects desired signals.

The circuit device of the first configuration example includes detection circuits 61 to 66 (first to n-th detection circuits), which perform analog front end processing on the detection signals from the physical quantity transducers SD1 to SD6, passive low-pass filters 11 to 14 (first to k-th passive low-pass filters, where k is an integer greater than or equal to 1 but smaller than or equal to n), which perform low-pass filtering on output signals from the detection circuits 61 to 64 (first to k-th detection circuits), a multiplexer 20, which receives output signals from the passive low-pass filters 11 to 14 and the detection circuits 65 and 66 ((k+1)-th to n-th detection circuits) as first to sixth input signals (first to n-th input signals) and selects an input signal from the first to sixth input signals in a time division manner, an amplification circuit 50, which amplifies an output signal from the multiplexer 20, and an A/D conversion circuit 30, which A/D-converts an output signal from the amplification circuit 50.

Each of the physical quantity transducers SD1 to SD6 is an element that detects any of a variety of physical quantities (for example, angular velocity, acceleration, temperature, or physical quantities equivalent thereto) and converts the detected physical quantity into an electric signal. For example, when the sensor includes a gyro sensor (acceleration sensor), the corresponding physical quantity transducer is, for example, a piezoelectric vibrator element or a capacitance-detecting vibrator element (vibration gyro). When the sensor includes an acceleration sensor, the corresponding physical quantity transducer is, for example, a capacitance-detecting element, a piezoelectric resistance element, or a heat sensing element.

The sensor may, for example, be a sensor that detects a plurality of physical quantities of the same kind (for example, multi-axis gyro sensor that detects angular velocities around a plurality of axes or multi-axis acceleration sensor that detects accelerations along a plurality of axes) or a sensor that detects a plurality of kinds of physical quantities (a combo sensor that is a combination of a gyro sensor and an acceleration sensor or the combo-sensor further combined with a temperature sensor).

The circuit device 100 is, for example, configured as an integrated circuit device and mounted along with the physical quantity transducers SD1 to SD6 on a substrate. For example, the circuit device 100 and the physical quantity transducers SD1 to SD6 may be encapsulated in a single package to form a module. Among the physical quantity transducers SD1 to SD6, an integrable physical quantity transducer (for example, a temperature sensor using dependence of forward voltage in a PN junction on temperature) may be contained in the circuit device 100.

Each of the detection circuits 61 to 66 receives differential detection signals from the corresponding one of the physical quantity transducers SD1 to SD6, detects a signal under detection from the differential signals, and outputs the signal under detection in the form of differential signals. Each of the detection circuits is formed, for example, of an amplification circuit and a filter circuit. The signal under detection is, for example, a signal corresponding to a physical quantity (such as angular velocity, acceleration, and temperature). For example, to detect angular velocity signals from a piezoelectric vibrator element, angular velocity signals modulated by the frequency at which the vibrator element is driven are outputted from the vibrator element, and the detection circuit performs amplification, wave detection, and other types of processing on the modulated angular velocity signals. Each of the physical quantity transducers may instead output a single-ended detection signal. In this case, the detection circuit converts the single-ended detection signal into differential signals.

Each of the passive low-pass filters 11 to 14 is a low-pass filter formed of a passive element, performs band limitation (or smoothens) the differential signals from the corresponding one of the detection circuits 61 to 64, and outputs the resultant differential signals. The configuration of each of the passive low-pass filters will be described with reference to the passive low-pass filter 11 by way of example. The passive low-pass filter 11 includes a resistive element RA1, which is provided between a node PL1 and a node PI1, a resistive element RB1, which is provided between a node NL1 and a node NI1, and a capacitor CA1, which is provided between the node PI1 and the node NI1. The nodes PL1 and NL1 are differential input nodes of the passive low-pass filter 11 (differential output nodes of detection circuit 61). The nodes PI1 and NI1 are differential output nodes of the passive low-pass filter 11 (first differential input nodes of multiplexer 20).

The multiplexer 20 includes switch elements SWA1 to SWA6, which are provided between nodes PI1 to P16 and a node PMQ, and switch elements SWB1 to SWB6, which are provided between nodes NI1 to N16 and a node NMQ. The nodes PIj and NIj (j=1, 2, . . . , n) are j-th differential input nodes of the multiplexer 20. The nodes PMQ and NMQ are differential output nodes of the multiplexer 20 (differential input nodes of amplification circuit 50). Each of the switch elements is formed, for example, of a transfer gate (P-type transistor and N-type transistor connected in parallel to each other). When the multiplexer 20 selects the j-th differential input nodes (j-th channel), the switch elements SWAj and SWBj are turned on so that the j-th differential input nodes are connected to the differential output nodes.

The amplification circuit 50 amplifies differential signals from the multiplexer 20 and outputs differential output signals to differential output nodes PAI and NAI (differential input nodes of A/D conversion circuit 30). The amplification circuit 50 is formed, for example, of an operational amplifier, a resistive element, and a capacitor. The amplification circuit 50 may have fixed gain or variable gain (programmable gain amplifier). The amplification circuit 50 may even be omitted. To drive an A/D conversion circuit having a large input load (input capacity), for example, a SAR-type (successive-approximation-type) A/D conversion circuit, it is desirable to provide the amplification circuit 50. On the other hand, when the A/D conversion circuit has a small input load, the amplification circuit 50 can be omitted in some cases.

The A/D conversion circuit 30 A/D-converts the differential signals from the amplification circuit 50 and outputs the converted signal in the form of a digital signal. The A/D conversion circuit 30 can, for example, be a SAR-type A/D conversion circuit or a delta-sigma-type A/D conversion circuit. The multiplexer 20 selects a channel sequentially from first to sixth channels and sequentially A/D-converts signals in the first to sixth channels in synchronization with the selection operation. For example, the multiplexer 20 switches one channel to another at 6×16 kHz, and the A/D conversion circuit 30 performs sampling at 6×16 kHz. In this case, the sampling frequency is 16 kHz per channel.

### 2. Second Configuration Example

In the first configuration example described above, the passive low-pass filters 11 to 14 are provided in the stage upstream of the multiplexer 20. Therefore, depending on the relationship between the time constant (cutoff frequency) of the passive low-pass filters 11 to 14 and the sampling frequency of the A/D conversion circuit 30, an inaccurate A/D-converted value is undesirably produced. The problem will be described below with reference to the first and second channels by way of example.

In the multiplexer 20, the switch elements SWA1 and SWB1 in the first channel are first tuned on, and the switch elements SWA2 and SWB2 in the second channel are then tuned on. Since the voltages (signal voltages) in the first and second channels typically differ from each other, the voltages at the output nodes PMQ and NMQ of the multiplexer 20 also change whenever the channel selection occurs. When the switch elements described above are turned on, the signals in the first and second channels pass through the passive low-pass filters 11 and 12, and the voltages at the output nodes PMQ and NMQ therefore change in accordance with the time constants of the passive low-pass filters 11 and 12.

For example, when a physical quantity transducer is an angular velocity sensor (vibrator element), the corresponding passive low-pass filter has a cutoff frequency of about 250 Hz (time constant of 4 ms). The cutoff frequency is so set that the magnitude of a detuning frequency (about 1 kHz, for example) component of the vibrator element can be reduced. The detuning frequency component is produced, for example, in a T-shaped or double-T-shaped piezoelectric vibrator element made of quartz or any other piezoelectric material, and the difference between a drive-side resonance frequency and a detection-side resonance frequency forms the detuning frequency. When a physical quantity transducer is an acceleration sensor, the corresponding passive low-pass filter has a cutoff frequency of about 5 kHz (time constant of 200 μs). The cutoff frequency is set for anti-aliasing that occurs in A/D conversion (about 16 kHz per channel).

On the other hand, the sampling frequency of the A/D conversion is, for example, 6×16 kHz=96 kHz (time constant of 10.4 μs), and the time constant in this case is much shorter than the time constant of the passive low-pass filter (about 1/400 of 4 ms, about 1/20 of 200 μs). Therefore, after the multiplexer 20 selects the second channel, sampling timing of the A/D conversion is reached before the output nodes PMQ and NMQ of the multiplexer are charged (the voltages at the output nodes PMQ and NMQ reach the voltages at the second differential input nodes PI2 and NI2).

To solve the problem described above, it is conceivable to use, for example, an active low-pass filter. However, since an active circuit produces noise (1/f noise produced by operational amplifier, for example), the noise is sampled by the A/D conversion circuit 30, lowering the S/N ratio. When an active circuit is provided in a stage upstream of the passive low-pass filters 11 to 14, the passive low-pass filters 11 to 14 reduce noise having frequencies higher than the cutoff frequency, and aliasing noise produced by the A/D conversion is therefore reduced. When each of the low-pass filters is formed of an active circuit, however, noise on the high-frequency side is directly A/D-converted, producing aliasing noise.

As described above, the low-pass filters in the stage upstream of the multiplexer 20 are desirably passive filters from the viewpoint of noise. In this case, however, signal transmission to the output nodes PMQ and NMQ of the multiplexer becomes slow, undesirably resulting in an inaccurate A/D-converted value.

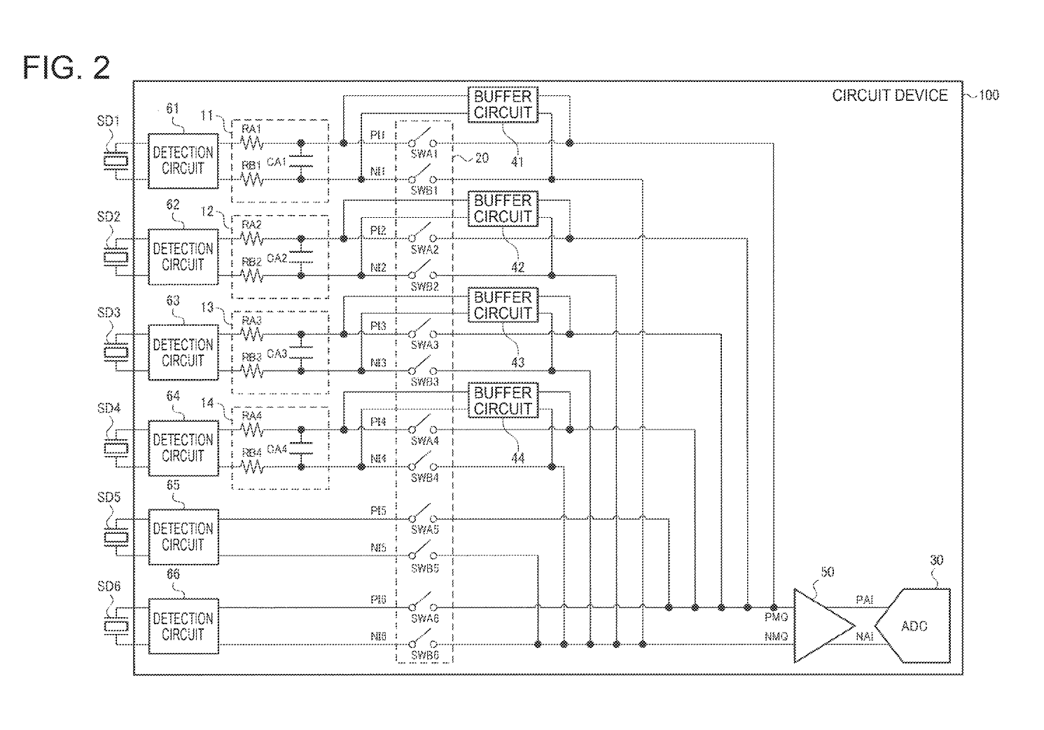

FIG. 2 shows a second configuration example of the sensor and the circuit device according to the present embodiment that can solve the problem described above. The sensor according to the second configuration example includes physical quantity transducers SD1 to SD6 (first to n-th physical quantity transducers, where n is an integer greater than or equal to 2) and a circuit device (detection device) that receives detection signals from the physical quantity transducers SD1 to SD6 and detects desired signals.

The circuit device according to the second configuration example includes detection circuits 61 to 66 (first to n-th detection circuits), passive low-pass filters 11 to 14 (first to k-th passive low-pass filters, where k is an integer greater than or equal to 1 but smaller than or equal to n), a multiplexer 20, buffer circuits 41 to 44 (first to k-th buffer circuits), an amplification circuit 50, and an A/D conversion circuit 30.

In the following description, the same components as those described in the first configuration example have the same reference characters and will not be described as appropriate. Further, the following description will be made of a third channel (such as passive low-pass filter 13, switch elements SWA3 and SWB3, and buffer circuit 43) among first to fourth channels where the buffer circuits are provided, and the first, second, and fourth channels have the same configuration and operate in the same manner.

The multiplexer 20 selects an input signal from first to sixth input signals (first to n-th input signals) inputted to first to sixth input nodes (first to n-th input nodes, first input node are nodes PI1 and NI1, for example) in a time division manner and outputs the selected input signal to the output nodes PMQ and NMQ. The A/D conversion circuit 30 receives the first to sixth input signals outputted from the multiplexer 20 to the output nodes PMQ and NMQ in a time division manner and A/D-converts the received signals in a time division manner. The buffer circuit 43 is provided between the third input node (i-th input node) and the output nodes PMQ, NMQ of the multiplexer 20.

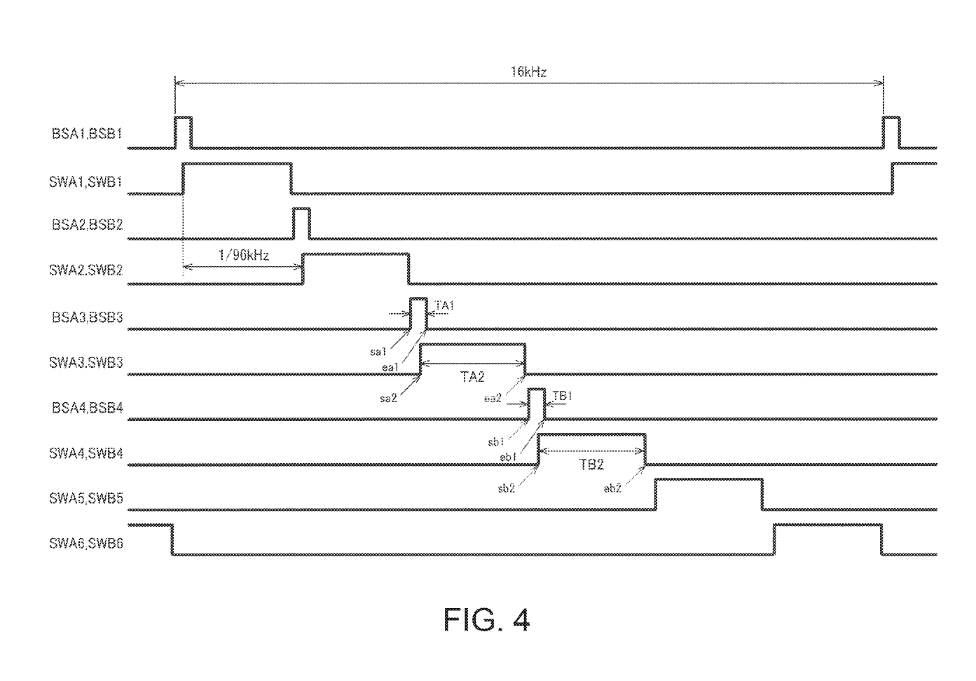

The thus provided buffer circuit 43 buffers the third input signal (i-th input signal) and outputs the buffered signal to the output nodes PMQ and NMQ in a first period TA1, as shown in FIG. 4. The multiplexer 20 selects the third input signal and outputs the selected signal to the output nodes PMQ and NMQ in a second period TA2. End timing ea2 of the second period TA2 comes after end timing ea1 of the first period TA1.

In the thus configured present embodiment, the buffer circuit 43 buffers the third input signal and drives the output nodes PMQ and NMQ of the multiplexer 20. As a result, when the multiplexer 20 selects the third channel, the output nodes PMQ and NMQ can be quickly driven to the voltage of the input signal, whereby an accurate A/D-converted value can be produced even when the stage upstream of the multiplexer 20 has poor driving capability.

Further, since the end timing ea2 of the second period TA2 comes after the end timing ea1 of the first period TA1, the buffer circuit 43 performs no driving operation when the sampling in the A/D conversion is performed. That is, since the buffer circuit 43 produces no noise at the time of sampling, an accurate A/D-converted value can be produced with no decrease in the S/N ratio.

Specifically, the A/D conversion circuit 30 samples the i-th input signal after the end timing ea1 of the first period TA1 but before the end timing ea2 of the second period TA2.

It is noted that the sampling is an action of determining a sampled voltage in A/D conversion, and that the sampling timing is timing at which a sampled voltage in A/D conversion is determined. For example, a sampling switch and a sampling capacitor are connected to each of the inputs of the A/D conversion circuit 30. The sampling capacitor is charged with input voltage for the period in which the sampling switch is ON, and the voltage (electric charge) across the sampling capacitor is determined when the sampling switch is turned off. In this case, the sampling is an action of turning the sampling switch off, and the sampling timing is the timing at which the sampling switch is turned off.

The A/D conversion circuit 30 performs the sampling in the second period TA2, for which the multiplexer 20 outputs the third input signal. In the present embodiment, performing the sampling in the second period TA2 after the end timing ea1 of the first period TA1 allows determination of the sampling voltage after the driving operation of the third buffer circuit 43. The third buffer circuit 43 can therefore perform driving operation without 1/f noise produced by an active circuit and other adverse effects.

Further, in the present embodiment, start timing sa2 of the second period TA2 comes after start timing sa1 of the first period TA1.

For example, when the multiplexer 20 selects the second channel, the multiplexer 20 outputs the second input signal. In this state, if the switch elements SWA3 and SWB3 in the third channel are turned on, the outputted second input signal is applied to the output of the third passive low-pass filter 13. Although the passive low-pass filter 13 should output the third input signal, the voltage of the third input signal undesirably changes due to the short circuit between the output of the multiplexer 20 and the output of the third passive low-pass filter 13. If the buffer circuit 43 performs the buffering in this state, voltage different from that of the third input signal is undesirably conveyed to the output of the multiplexer.

In this regard, according to the present embodiment, since the start timing sa1 of the first period TA1 comes before the start timing sa2 of the second period TA2, the buffer circuit 43 performs the buffering before the switch elements SWA3 and SWB3 in the third channel are turned on. Since the output from the passive low-pass filter 13 is the third input signal before the switch elements SWA3 and SWB3 in the third channel are turned on, the buffer circuit 43 can correctly drive the output of the multiplexer with the third input signal.

Further, in the present embodiment, the buffer circuit 44 ((i+1)-th buffer circuit, where i is smaller than or equal to n−1) buffers the fourth input signal ((i+1)-th input signal) and outputs the buffered signal to the output nodes PMQ and NMQ in a third period TB1. The multiplexer 20 selects the fourth input signal and outputs the selected signal to the output nodes PMQ and NMQ in a fourth period TB2. End timing of the fourth period TB2 is set at a point after end timing of the third period TB1.

Further, start timing sb1 of the third period TB1 is set at a point after the end timing ea2 of the second period TA2.

In the second period TA2, the multiplexer 20 connects third input nodes P13 and N13 to the output nodes PMQ and NMQ. In the second period TA2, if the buffer circuit 44 outputs the fourth input signal to the output nodes PMQ and NMQ, the fourth input signal is undesirably applied to the output of the passive low-pass filter 13. To allow the output of the passive low-pass filter 13 to return to the original third input signal, it take time approximately corresponding to the time constant of the passive low-pass filter 13, and the output of the passive low-pass filter 13 is therefore likely not to return to the third input signal before the following selection in the time division operation.

In this regard, according to the present embodiment, since the start timing sb1 of the third period TB1 is set at a point after the end timing ea2 of the second period TA2, the fourth input signal is never applied to the output of the passive low-pass filter 13.

Further, in the present embodiment, the third input signal (i-th input signal) to the multiplexer 20 is the output signal from the passive low-pass filter 13.

In this configuration, when the multiplexer 20 selects the third channel (i-th channel), the output signal from the passive low-pass filter 13 is outputted to the output of the multiplexer 20. In general, the cutoff frequency of a low-pass filter is lower than the Nyquist frequency (half of sampling frequency per channel), but the time division operation performed by the multiplexer 20 increases the sampling frequency in the A/D conversion (sampling frequency corresponding to 6 channels). A state in which the stage upstream of the multiplexer 20 has poor driving capability therefore occurs, resulting in an inaccurate A/D-converted value.

In this regard, according to the present embodiment, the buffer circuit 43 drives the output of the multiplexer 20 with the third input signal before the A/D conversion circuit 30 performs sampling. The output of the multiplexer 20 can therefore be quickly driven with the third input signal, whereby an accurate A/D-converted value can be produced.

Further, in the present embodiment, a detection signal from the physical quantity transducer SD3 is inputted to the detection circuit 63. The third input signal (i-th input signal) to the multiplexer 20 is the output signal that is outputted by the detection circuit 63 and inputted via the passive low-pass filter 13.

In the configuration described above, the passive low-pass filter 13 removes noise produced by the detection circuit 63 in such a way that noise components having frequencies higher than the cutoff frequency of the passive low-pass filter 13 are removed. Further, the passive low-pass filter 13, which is a passive circuit, does not form a noise source and does not therefore lower the S/N ratio of an A/D-converted value even when no noise removal is performed in the stage downstream of the passive low-pass filter 13.

Further, in the present embodiment, the physical quantity transducer SD3 (at least one of first to k-th physical quantity transducers) may, for example, be an angular velocity sensor (piezoelectric vibrator element and capacitance-detecting vibrator element, for example).

Further, in the present embodiment, the physical quantity transducer SD3 (at least one of first to k-th physical quantity transducers) may, for example, be an acceleration sensor (capacitance-detecting element, piezoelectric resistance element, and heat sensing element, for example).

In the case of an angular velocity sensor, a low-pass filter is required, for example, to smoothen a detection signal (smoothen output from switching mixer, which will be described later) or remove a detuning frequency component. In the case of an acceleration sensor, a low-pass filter is required, for example, for anti-aliasing. As described above, in the present embodiment, use of a passive low-pass filter can prevent a decrease in the S/N ratio, and provision of the buffer circuit 43 allows generation of an accurate A/D-converted value.

Further, in the present embodiment, since the third input signal (i-th input signal) is formed of differential signals, and the output node of the multiplexer 20 is formed of the differential nodes PMQ and NMQ. The A/D conversion circuit 30 A/D-converts the third input signal outputted to the differential nodes PMQ and NMQ.

Specifically, the third input node of the multiplexer 20 is formed of differential nodes, and the differential nodes are formed of the first node P13 and the second node N13. The output differential nodes are formed of the first node PMQ and the second node NMQ. The first switch element SWA3 is provided between the first node P13 and the node PMQ, and the second switch element SWB3 is provided between the second node N13 and the node NMQ. When the first and second switch elements SWA3, SWB3 are turned on, the third input signal is outputted to the output nodes, and the A/D conversion circuit 30 samples the third input signal.

The configuration described above allows the multiplexer 20 to select differential signals in a time division manner, and the differential signals can be A/D-converted. As a result, differential analog processing in a stage upstream of the multiplexer 20 and A/D conversion can be performed, whereby advantages, such as improvement in the S/N ratio, reduction in in-phase noise, and other types of benefit of differential processing, can be provided. Since a detection signal from an angular velocity sensor or any other physical quantity sensor is a minute signal, analog processing performed thereon requires a large amount of gain, which undesirably results in a decrease in the S/N ratio, but use of a differential circuit allows improvement in the S/N ratio in the present embodiment.

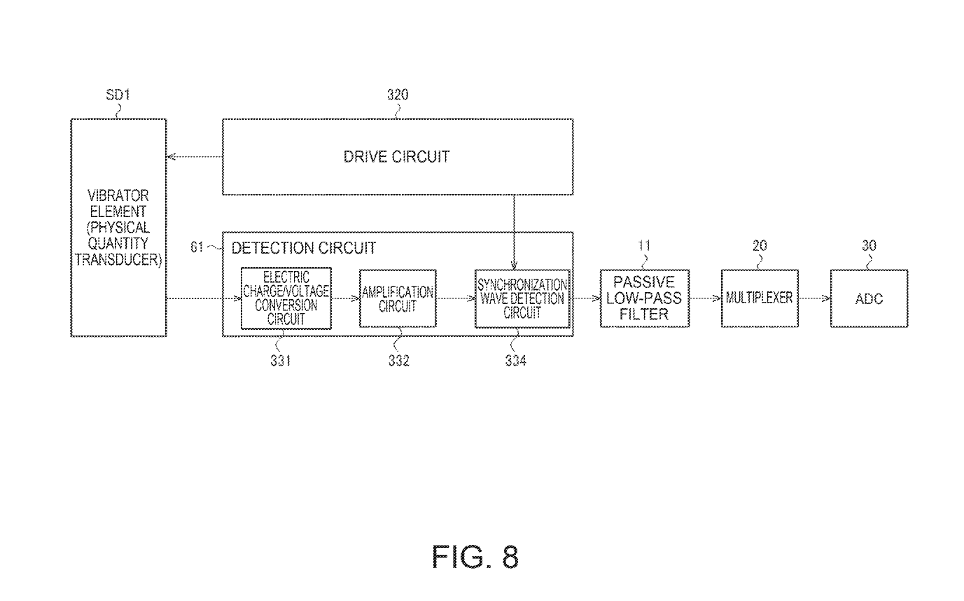

Further, in the present embodiment, the detection circuit 63 may include a synchronization detection circuit 334, as will be described later with reference to FIG. 8. For example, when the physical quantity transducer SD3 is a vibrator element (angular velocity sensor), the detection circuit 63 includes the synchronization detection circuit 334.

For example, when the synchronization detection circuit 334 is provided in the final stage of the detection circuit 63, the output from the synchronization detection circuit 334 has a waveform containing high frequency components (an effective value of the waveform is a signal under detection). The passive low-pass filter 13 smoothens the waveform containing high frequency components and extracts the signal under detection (signal that belongs to desired band (band within which physical quantity changes)). Instead, band limitation of the passive low-pass filter 13 allows removal of an unnecessary signal (detuning frequency component described above, for example). The passive low-pass filter 13 needs to be provided in the present embodiment from the reasons describe above, and provision of the buffer circuit 43 allows generation of an accurate A/D-converted value, as described above.

Further, in the present embodiment, the detection circuit 63 includes an amplification circuit 332, which is provided in a stage upstream of the synchronization detection circuit 334, and an electric charge/voltage conversion circuit 331, which is provided in a stage upstream of the amplification circuit 332, as will be described later with reference to FIG. 8.

For example, in a physical quantity transducer, such as a piezoelectric vibrator element (angular velocity sensor), a current signal is outputted as the detection signal. According to the present embodiment, the electric charge/voltage conversion circuit 331 can convert the current signal into a voltage signal, and the amplification circuit 332 can amplify the voltage signal. The detection signal is a signal carried by a carrier wave having a frequency equal to the vibration frequency of the vibrator element, and the detection signal can be detected by the synchronization detection circuit 334.

### 3. Detailed Configuration

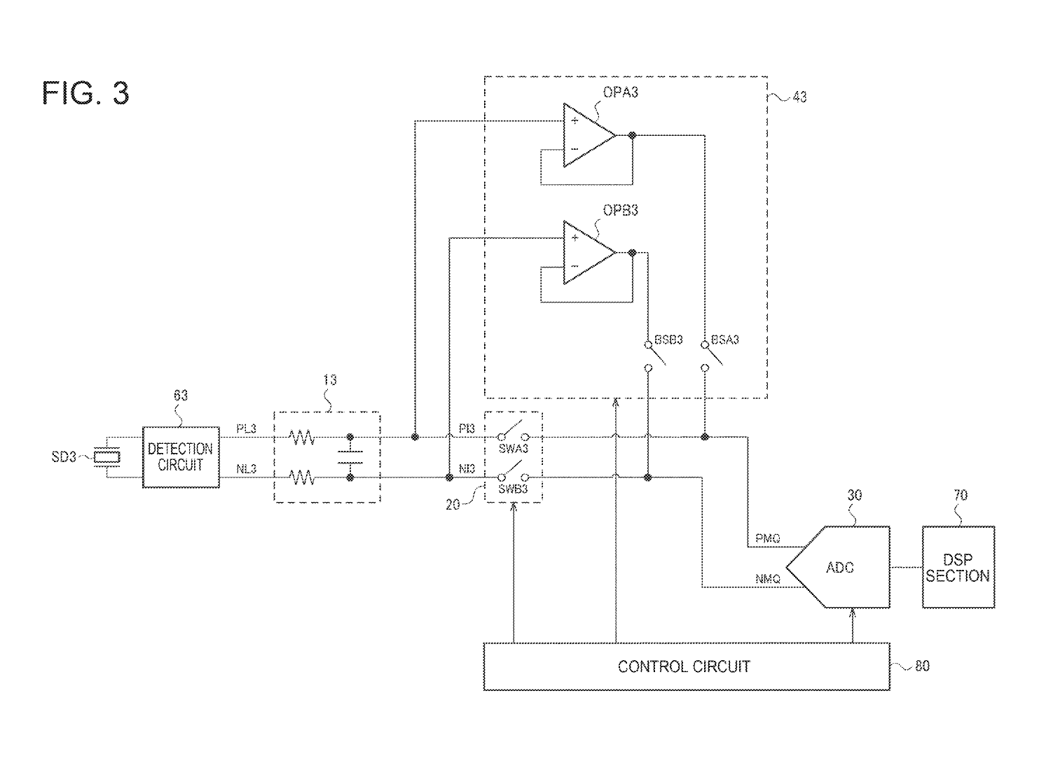

FIG. 3 shows an example of the detailed configurations of the buffer circuits and the sensor. FIG. 3 shows the buffer circuit 43 among the buffer circuits 41 to 44 by way of example, and the buffer circuits 41, 42, and 44 can be configured in the same manner. Although the amplification circuit 50 is omitted in FIG. 3, the amplification circuit 50 may be provided, as in FIG. 2.

The sensor in FIG. 3 includes the physical quantity transducer SD3, the detection circuit 63, the passive low-pass filter 13, the multiplexer 20, the buffer circuit 43, the A/D conversion circuit 30, a control circuit 80, and a DSP section (processor). In the following description, the same components as those described in the first and second configuration examples have the same reference characters and will not be described as appropriate.

The buffer circuit 43 includes amplifier circuits OPA3 and OPB3, which amplify the third input signal (i-th input signal), and switch elements BSA3 and BSB3, which are provided between the outputs of the amplifier circuits OPA3, OPB3 and the output nodes PMQ, NMQ of the multiplexer 20. The switch elements BSA3 and BSB3 are turned on in the first period TA1, as shown in FIG. 4.

In this configuration, in the first period TA1, for which the switch elements BSA3 and BSB3 are ON, the amplifier circuits OPA3 and OPB3 can buffer the third input signal and output the buffered signal to the output nodes PMQ and NMQ of the multiplexer 20. Further, when the switch elements BSA3 and BSB3 are turned off, the outputs of the amplifier circuits OPA3 and OPB3 can be isolated from the output nodes PMQ and NMQ of the multiplexer 20. Noise produced by the amplifier circuits OPA3 and OPB3 is thus isolated from the input of the A/D conversion circuit 30.

Specifically, the buffer circuit 43 includes the first amplification circuit OPA3, which is provided between the node P13 and the node PMQ, the second amplification circuit OPB3, which is provided between the node N13 and the node NMQ, the first switch element BSA3, which is provided between the output of the first amplification circuit OPA3 and the node PMQ, and the second switch element BSB3, which is provided between the output of the second amplification circuit OPB3 and the node NMQ.

Each of the first and second amplification circuit OPA3, OPB3 includes an operational amplifier and configured to be a voltage follower. Each of the amplification circuits is not necessarily configured as described above and only needs to be an active circuit that drives the corresponding output node on the basis of an input signal to the multiplexer 20.

Each of the first and second switch elements BSA3, BSB3 is formed, for example, of a transfer gate (P-type transistor and N-type transistor connected in parallel to each other), a P-type transistor, or an N-type transistor.

The control circuit 80 is a circuit that controls each portion of the circuit device. For example, the control circuit 80 outputs control signals that control the switch elements of the multiplexer 20, control signals that control the switch elements of the buffer circuits 41 to 44, and a control signal that controls the A/D conversion circuit 30. The DSP section 70 is a processor that processes an A/D-converted value from the A/D conversion circuit 30. The DSP section 70 may be built in as a gate array in the circuit device or may be provided as a discrete processor. Instead, a gate array in which the control circuit 80 and the DSP section 70 are integrated with each other may be built in the circuit device. The DSP section 70 produces digital signals in the channels from A/D-converted values in a time division manner. For example, the DSP section 70 performs band limitation provided by a digital filter, removal of a DC offset, calculation of an angle and a position (travel) provided by integration, and other types of processing on an angular velocity signal and an acceleration signal.

FIG. 4 is a timing chart in accordance with which the buffer circuits 41 to 44 and the multiplexer 20 operate. FIG. 4 is a timing chart showing control signals that control the switch elements of the buffer circuits and the multiplexer. In the timing chart, the high level (first logic level) represents an active control signal, and the low level (second logic level) represents an inactive control signal.

The states of the switch elements BSA3 and BSB3 of the buffer circuit 43 are changed from OFF to ON at the start timing sa1 of the first period TA1, as shown in FIG. 4. The states of the switch elements SWA3 and SWB3 of the multiplexer 20 are then changed from OFF to ON at the start timing sa2 of the second period TA2. The states of the switch elements BSA3 and BSB3 of the buffer circuit 43 are then changed from ON to OFF at the end timing eat of the first period TA1. The states of the switch elements SWA3 and SWB3 of the multiplexer 20 are then changed from ON to OFF at the end timing ea2 of the second period TA2.

Since the multiplexer 20 selects one channel from the first to sixth channels in a time division manner, the same action at that for the third channel described above is successively repeated for the first to fourth channels. The multiplexer 20 then selects one channel from the fifth and sixth channels in a time division manner. In the case of the fifth and sixth channels, however, only the corresponding switch elements of the multiplexer 20 are turned on because no buffer circuit is provided in the fifth and sixth channels. The selection of the sixth channel is followed by the selection of the first channel again. The period for which the switch elements of the multiplexer 20 in each of the channels are ON is so set not as to overlap with the period for which the switch elements of the buffer circuit in the following channel. For example, after the switch elements SWA3 and SWB3 of the multiplexer 20 in the third channel are turned off (ea2), the switch elements of the buffer circuit in the fourth channel are turned on (sb1).

The channel selection cycle starts from the rising edge of a control signal that controls a single switch element (BSA1, for example) and ends at the following rising edge of the control signal and is, for example, a reciprocal of 16 kHz. The cycle of the time division operation performed by the multiplexer 20 starts from the rising edge of a control signal that controls a switch element in a certain channel (SWA1, for example) and ends at the rising edge of a control signal that controls the switch element in the following channel (SWA2). In the example shown in FIG. 4, in which the number of channels is 6, the cycle of the time division operation performed by the multiplexer 20 is a reciprocal of 6×16=96 kHz.

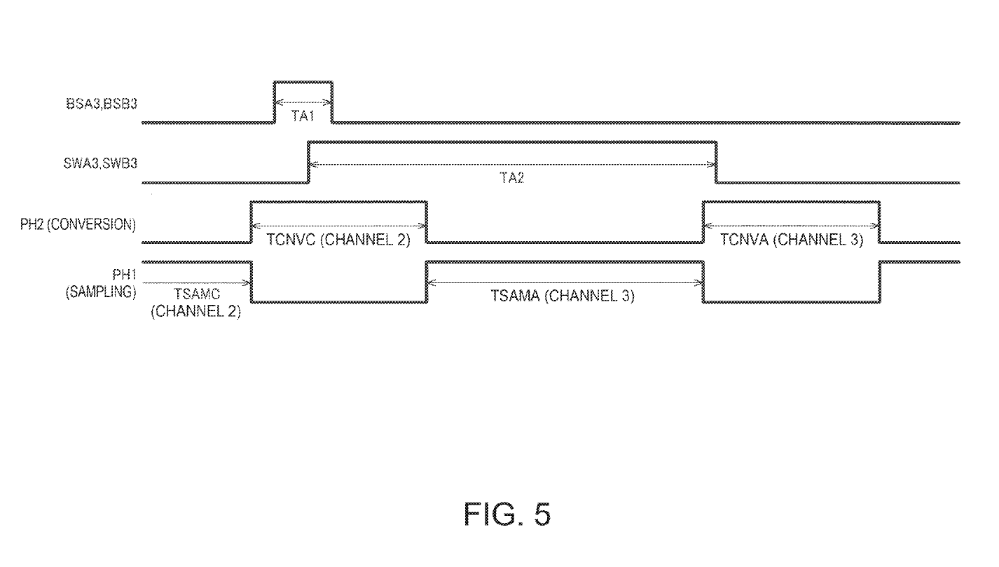

FIG. 5 is a timing chart in accordance with which the buffer circuit 43, the multiplexer 20, and the A/D conversion circuit 30 operate. FIG. 5 is a timing chart of control signals that control the switch elements in the third channel and a control signal that controls the A/D conversion circuit 30. In the timing chart, the high level (first logic level) represents an active control signal, and the low level (second logic level) represents an inactive control signal. The following description will be made with reference to a case where the A/D conversion circuit 30 is a SAR-type circuit.

The ON and OFF control of the switch elements BSA3 and BSB3 of the buffer circuit 43 and the switch elements SWA3 and SWB3 of the multiplexer 20 has already been described with reference to FIG. 4. Reference character PH1 denotes a control signal that controls the sampling performed by the A/D conversion circuit 30, and reference character PH2 denotes a controls signal that controls the successive approximation operation performed by the A/D conversion circuit 30. The signal PH1 becomes active in a period TSAMA, and the A/D conversion circuit 30 captures a third-channel signal into the sampling capacitor in the period TSAMA. The sampling timing described above corresponds to the end timing of the period TSAMA and is timing at which the sampling capacitor holds the third-channel signal. The signal PH2 becomes active in a period TCNVA, and the A/D conversion circuit 30 performs successive approximation on the third-channel signal (signal held by sampling capacitor) to produce an A/D-converted value in a period TSAMA.

The start timing of the sampling period TSAMA comes after the start timing of the ON period TA2, for which the switch elements SWA3 and SWB3 of the multiplexer 20 are ON, and the end timing of the sampling period TSAMA comes before the end timing of the ON period TA2, for which the switch elements SWA3 and SWB3 of the multiplexer 20 are ON but after the end timing of the ON period for which the switch elements BSA3 and BSB3 of the buffer circuit 43 are ON. The start timing of the successive approximation period TCNVA comes after the end timing of the sampling period TSAMA.

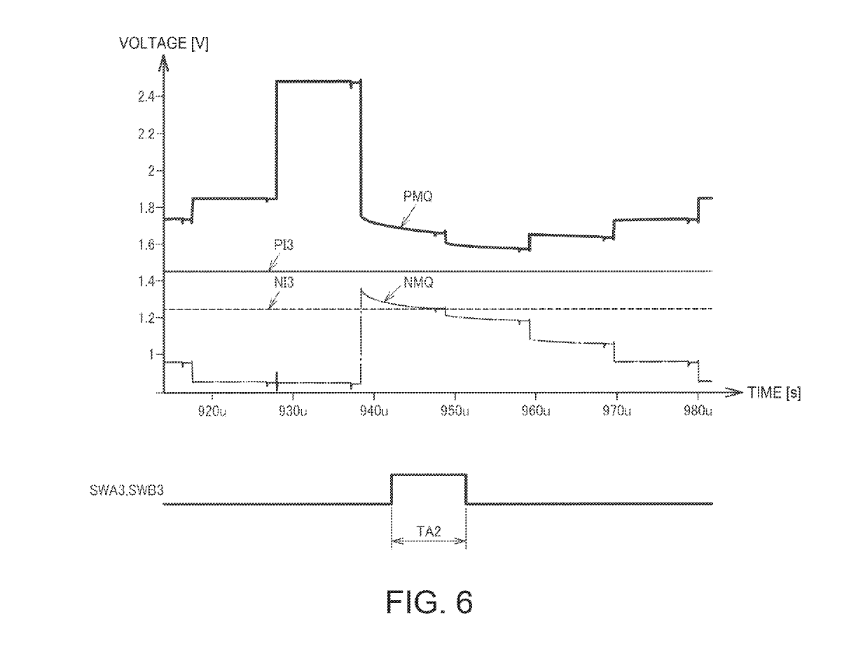

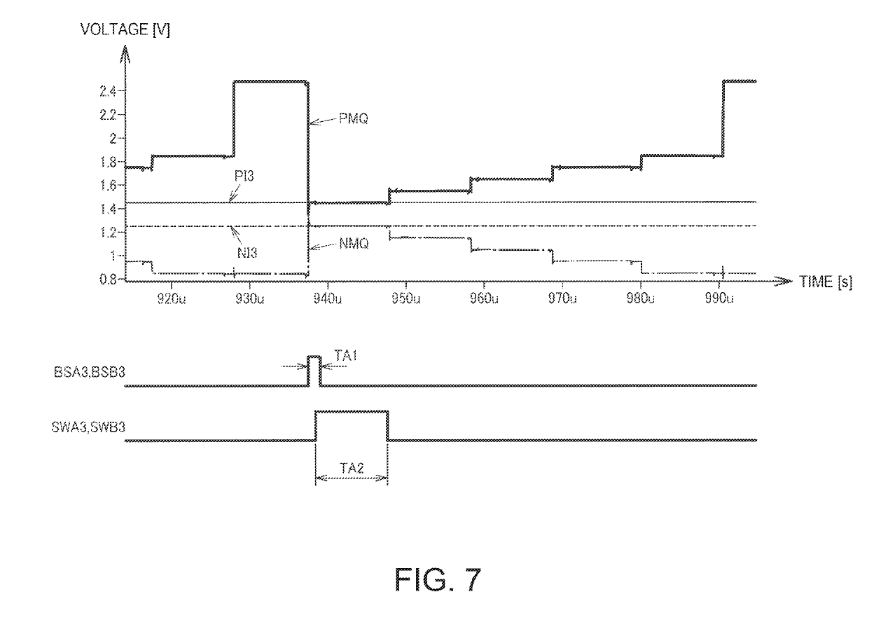

FIGS. 6 and 7 show simulation results in the present embodiment. FIG. 6 shows a result of simulation of the output from the multiplexer 20 in the first configuration example, in which no buffer circuit is provided. FIG. 7 shows a result of simulation of the output from the multiplexer 20 in the second configuration example, in which the buffer circuits are provided.

In the period TA2, for which the switch elements SWA3 and SWB3 of the multiplexer 20 in the third channel are ON, the voltages at the input nodes P13 and N13 in the third channel should coincide with the voltages at the output nodes PMQ and NMQ. When no buffer circuit is provided, however, the voltages at the input nodes P13 and N13 in the third channel do not coincide with the voltages at the output nodes PMQ and NMQ in the period TA2, as shown in FIG. 6. The simulation shows that the voltages at the output nodes PMQ and NMQ approach the voltages at the input nodes P13 and N13 in the third channel but still do not coincide therewith in the period TA2.

On the other hand, when the buffer circuits are provided, in the period TA1, for which the switch elements BSA3 and BSB3 of the buffer circuit are ON, the voltages at the input nodes P13 and N13 in the third channel coincide with the voltages at the output nodes PMQ and NMQ. Further, the voltages at the input nodes P13 and N13 in the third channel coincide with the voltages at the output nodes PMQ and NMQ also in the second period TA2. As described above, even when the cutoff frequency of the passive low-pass filters is lower than the frequency of the time division operation, provision of the buffer circuits allows quick channel selection.

### 4. Detection Circuit

The detection circuit will next be described in detail with reference to a case where the physical quantity transducer SD1 is a vibrator element (angular velocity sensor). FIG. 8 shows an example of the sensor configuration in this case. FIG. 8 only shows the detection circuit 61 corresponding to the vibrator element SD1 among the detection circuits 61 to 64, and the detection circuits 62 to 64 can also be configured in the same manner when the physical quantity transducers SD2 to SD4 are vibrator elements.

The sensor in FIG. 8 includes the vibrator element SD1, a drive circuit 320, the detection circuit 61, the passive low-pass filter 11, the multiplexer 20, and the A/D conversion circuit 30. The detection circuit 61 includes the electric charge/voltage conversion circuit 331, the amplification circuit 332, and the synchronization detection circuit 334. The drive circuit 320 drives the vibrator element SD1 by using a drive signal. A detection signal (current signal) from the vibrator element SD1 is inputted to the electric charge/voltage conversion circuit 331 of the detection circuit 61. An output signal from the electric charge/voltage conversion circuit 331 is inputted to the amplification circuit 332. The synchronization detection circuit 334 performs synchronous detection on an output signal from the amplification circuit 332 on the basis of a synchronization signal (signal that synchronizes with drive signal) from the drive circuit 320 to extract a desired signal.

The passive low-pass filter 11 then performs low-pass filtering for signal smoothening and removal of unnecessary signals (detuning frequency component, for example) and outputs a signal having detected voltage to the multiplexer 20. The detected voltage (difference between differential signals) is DC voltage proportional to the angular velocity (dps), and the greater the angular velocity, the higher the detected voltage.

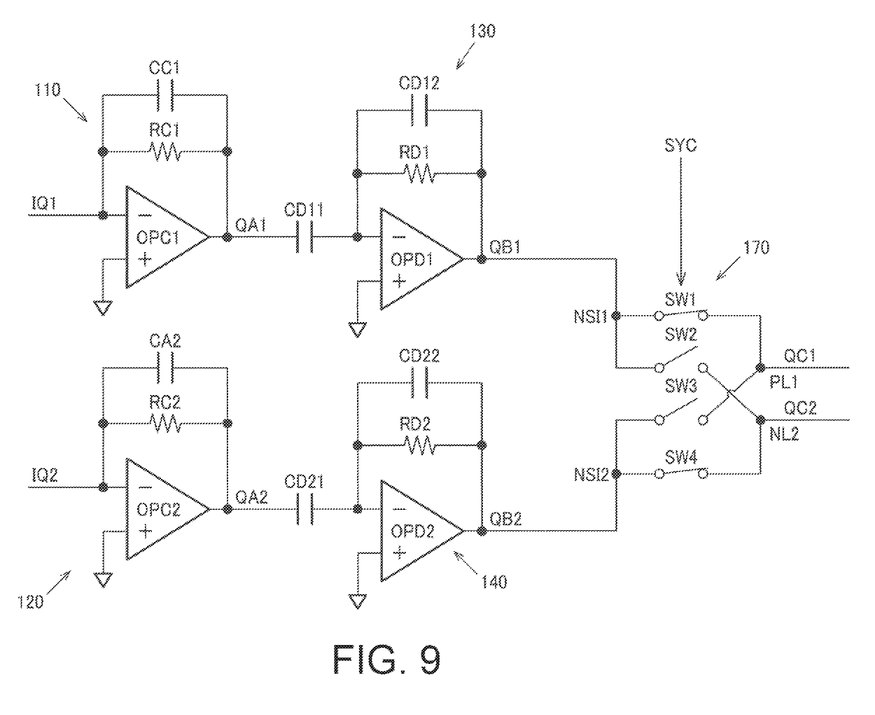

FIG. 9 shows an example of a detailed configuration of the detection circuit. The detection circuit includes a first electric charge/voltage conversion circuit 110, a second electric charge/voltage conversion circuit 120, a first gain adjustment amplifier 130, a second gain adjustment amplifier 140, and a switching mixer 170. The electric charge/voltage conversion circuits 110 and 120 correspond to the electric charge/voltage conversion circuit 331 in FIG. 8, the gain adjustment amplifiers 130 and 140 correspond to the amplification circuit 332 in FIG. 8, and the switching mixer 170 corresponds to the synchronization detection circuit 334 in FIG. 8.

The electric charge/voltage conversion circuit 110 includes an operational amplifier OPC1, a capacitor CC1, and a resistive element RC1, and the electric charge/voltage conversion circuit 120 includes an operational amplifier OPC2, a capacitor CC2, and a resistive element RC2.

In the operational amplifier OPC1 of the electric charge/voltage conversion circuit 110, the potential at the non-inverted input terminal (first input terminal in a broad sense) is fixed. Specifically, in the operational amplifier OPC1 of the electric charge/voltage conversion circuit 110, the potential at the non-inverted input terminal is set at a predetermined value (AGND). The capacitor CC1 and the resistive element RC1 are provided between the output node of the electric charge/voltage conversion circuit 110 and the node of the inverted input terminal (second input terminal in a broad sense) of the operational amplifier OPC1. Reference character IQ1 denotes one of differential output currents (first output current) from the vibrator element SD1, and reference character QA1 denotes output voltage from the electric charge/voltage conversion circuit 110.

In the operational amplifier OPC2 of the electric charge/voltage conversion circuit 120, the potential at the non-inverted input terminal is fixed. Specifically, in the operational amplifier OPC2 of the electric charge/voltage conversion circuit 120, the potential at the non-inverted input terminal is set at the predetermine value. The capacitor CC2 and the resistive element RC2 are provided between the output node of the electric charge/voltage conversion circuit 120 and the node of the inverted input terminal of the operational amplifier OPC2. Reference character IQ1 denotes the other one of differential output currents (second output current) from the vibrator element SD1, and reference character QA2 denotes output voltage from the electric charge/voltage conversion circuit 120.

The gain adjustment amplifier 130 includes an operational amplifier OPD1, first and second capacitors CD11, CD12, and a resistive element RD1. The gain adjustment amplifier 140 includes an operational amplifier OPD2, first and second capacitors CD21, CD22, and a resistive element RD2.

In the operational amplifier OPD1 of the gain adjustment amplifier 130, the potential at the non-inverted input terminal (first input terminal) is set at the predetermined value (AGND). The capacitor CD11 is provided between the output node of the first electric charge/voltage conversion circuit 110 and the node of the inverted input terminal (second input terminal) of the operational amplifier OPD1. The capacitor CD12 and the resistive element RD1 are provided between the output node of the gain adjustment amplifier 130 and the node of the inverted input terminal of the operational amplifier OPD1. Reference character QB1 denotes output voltage from the gain adjustment amplifier 130.

In the operational amplifier OPD2 of the gain adjustment amplifier 140, the potential at the non-inverted input terminal is set at the predetermined value. The capacitor CD21 is provided between the output node of the first electric charge/voltage conversion circuit 120 and the node of the inverted input terminal of the operational amplifier OPD2. The capacitor CD22 and the resistive element RD2 are provided between the output node of the gain adjustment amplifier 140 and the node of the inverted input terminal of the operational amplifier OPD2. Reference character QB2 denotes output voltage from the gain adjustment amplifier 140.

In the gain adjustment amplifier 130, at least one of the capacitors CD11 and CD12 is a variable capacity capacitor. Also in the gain adjustment amplifier 140, at least one of the capacitors CD21 and CD22 is a variable capacity capacitor. The capacity of the variable capacity capacitors is variably set by the control circuit 80 (register). When the capacity of each of the capacitors CD11 and CD12 is set at C1, and the capacity of each of the capacitors CD21 and CD22 is set at C2, for example, the gain of each of the gain adjustment amplifiers 130 and 140 is set at C2/C1, which is the capacity ratio between C1 and C2.

Each of the gain adjustment amplifiers 130 and 140 in FIG. 9 has the frequency characteristic of a high-pass filter. That is, the capacitor CD11 and the resistive element RD1 of the gain adjustment amplifier 130 form a high-pass filter, and the capacitor CD21 and the resistive element RD2 of the gain adjustment amplifier 140 form a high-pass filter. The gain adjustment amplifier 130 thus has the frequency characteristic of a high-pass filter that reduces (removes) 1/f noise produced by the electric charge/voltage conversion circuit 110. Similarly, the gain adjustment amplifier 140 has the frequency characteristic of a high-pass filter that reduces (removes) 1/f noise produced by the electric charge/voltage conversion circuit 120.

The switching mixer 170 has switch elements SW1 to SW4. The switch element SW1 is provided between a first input node NSI1 and a first output node PL1 of the switching mixer 170. The switch element SW2 is provided between the first input node NSI1 and a second output node NL2 of the switching mixer 170. The switch element SW3 is provided between a second input node NSI2 and the first output node PL1 of the switching mixer 170. The switch element SW4 is provided between the second input node NSI2 and the second output node NL2. Each of the switch elements SW1 to SW4 can be formed, for example, of a MOS transistor (NMOS transistor or transfer gate, for example).

The switch elements SW1 and SW2 are exclusively turned on and off and the switch elements SW3 and SW4 are exclusively turned on and off on the basis of a sync signal SYC from the drive circuit 320. For example, when the sync signal SYC has a high level (first level), the switch elements SW1 and SW4 are turned on, and the switch elements SW2 and SW3 are turned off. On the other hand, when the sync signal SYC has a low level (second level), the switch elements SW2 and SW3 are turned on, and the switch elements SW1 and SW4 are turned off. As a result, the signals QB1 and QB2 from the gain adjustment amplifiers 130 and 140, which form differential signals, undergo synchronous detection, and signals after the synchronous detection are outputted as signals QC1 and QC2, which form differential signals. For example, the signals QB1 and QB2 are reversed-phase sinusoidal waves. In this case, the positive-electrode side of the signals QB1 and QB2 (high-potential side with respect to AGND) is outputted as the signal QC1, and the negative-electrode side of the signals QB1 and QB2 (low-potential side with respect to AGND) is outputted as the signal QC2.

### 5. A/D Conversion Circuit

The A/D conversion circuit 30 will next be described in detail with reference to the case where the A/D conversion circuit 30 is a SAR-type circuit.

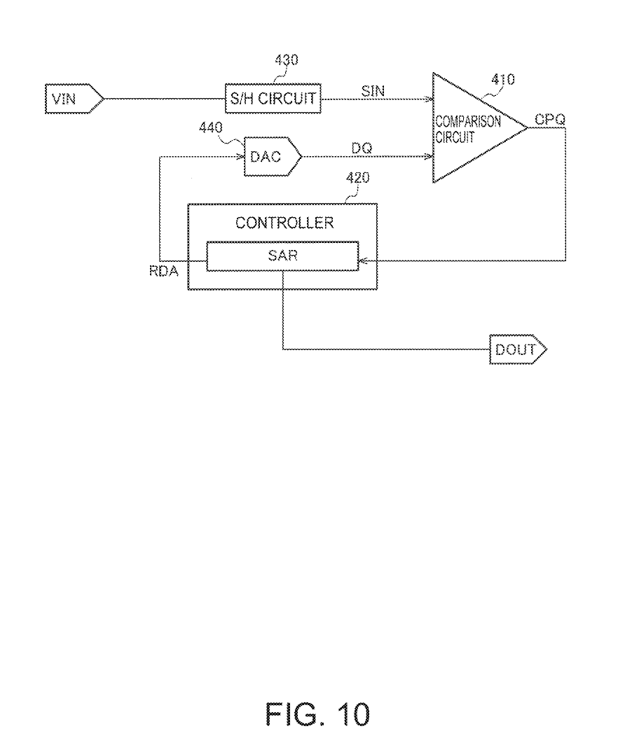

FIG. 10 shows an example of a basic configuration of the A/D conversion circuit in the present embodiment. The A/D conversion circuit shown in FIG. 10 includes a comparison circuit 410, a controller 420, an S/H (sample/hold) circuit 430, and a D/A conversion circuit 440.

The S/H circuit 430 is a circuit that samples and holds an input signal VIN to be A/D-converted. In a case of an electric charge redistribution type, as in a configuration example described later, the function of the S/H circuit 430 may be incorporated in the D/A conversion circuit 440. The D/A conversion circuit 440 D/A-converts successive approximation data RDA from the controller 420 and outputs a D/A output signal DQ, which is an analog signal and corresponds to the successive approximation data RDA. The comparison circuit 410 is achieved by using a comparator and compares a sampling signal SIN with the D/A output signal DQ. The controller 420 has a successive approximation register SAR and outputs the successive approximation data RDA to the D/A conversion circuit 440. The controller 420 outputs A/D conversion data DOUT, which is a value produced in the successive approximation and registered in the successive approximation register SAR. The successive approximation register SAR is a register that stores a register value set by a comparison result signal CPQ from the comparison circuit 410. The controller 420 further controls each circuit block of the A/D conversion circuit.

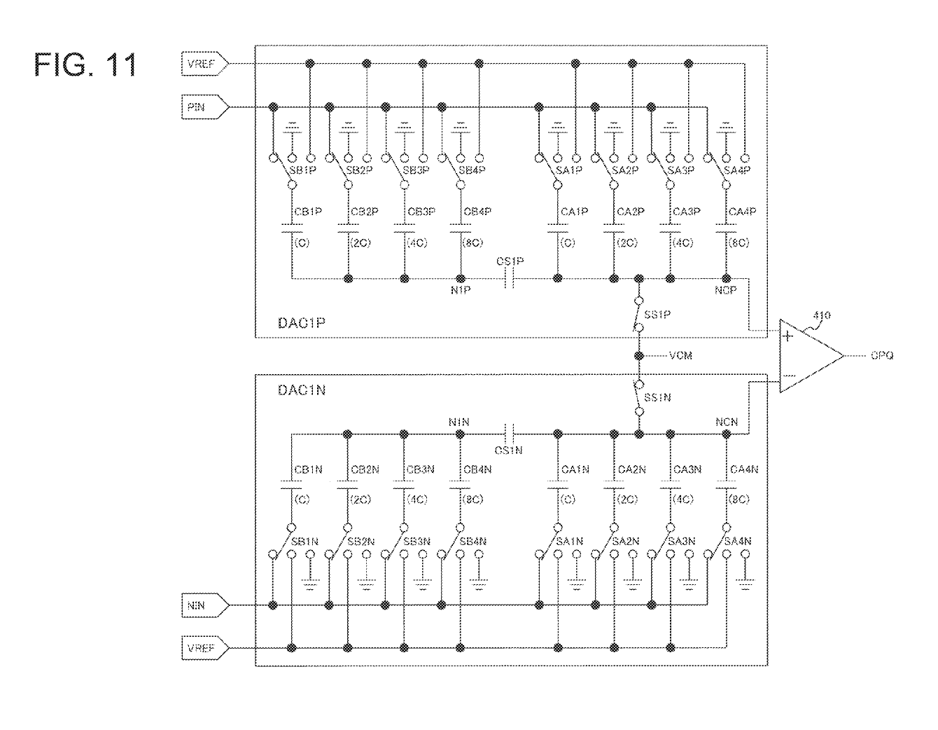

FIG. 11 shows an example of detailed configurations of the S/H circuit, the D/A conversion circuit, and the comparison circuit. FIG. 11 shows an example of a full differential type configuration, and the function of the S/H circuit is incorporated in the D/A conversion circuit. The following description will be made of a case where the number of bits in the A/D conversion is 8.

The configuration example shown in FIG. 11 includes a D/A conversion circuit DAC1P, which is connected to the non-inverted input terminal of the comparison circuit 410, a D/A conversion circuit DAC1N, which is connected to the inverted input terminal of the comparison circuit 410, and the comparison circuit 410.

The D/A conversion circuit DAC1P includes a capacitor array having capacitors CA1P to CA4P and capacitors CB1P to CB4P, a series capacitor CS1P provided between a node NCP of the non-inverted input terminal of the comparison circuit 410 and a node N1P, a switch array having switch elements SA1P to SA4P and switch elements SB1P to SB4P, and a switch element SS1P provided between the node NCP and a node of common voltage VCM.

Each of the switch elements SA1P to SA4P and SB1P to SB4P has first to fourth terminals, and the first terminal is connected to any of the second to fourth terminals. The first terminals of the switch elements SA1P to SA4P and SB1P to SB4P are connected to one-side ends of the capacitors CA1P to CA4P and CB1P to CB4P. The second, third, and fourth terminals of each of the switch elements SA1P to SA4P and SB1P to SB4P are connected to the node of a non-inverted-side input signal PIN, the node of ground voltage (first reference voltage), and the node of reference voltage VREF (second reference voltage), respectively. The other-side ends of the capacitors CA1P to CA4P are connected to the node NCP of the non-inverted input terminal of the comparison circuit 410 (node facing one end of series capacitor CS1P). The other-side ends of the capacitors CB1P to CB4P are connected to the node N1P facing the other end of the series capacitor CS1P.

The D/A conversion circuit DAC1N includes a capacitor array having capacitors CA1N to CA4N and capacitors CB1N to CB4N, a series capacitor CS1N provided between a node NCN of the inverted input terminal of the comparison circuit 410 and a node N1N, a switch array having switch elements SA1N to SA4N and switch elements SB1N to SB4N, and a switch element SS1N provided between the node NCN and a node of the common voltage VCM.

Each of the switch elements SA1N to SA4N and SB1N to SB4N has first to fourth terminals, and the first terminal is connected to any of the second to fourth terminals. The first terminals of the switch elements SA1N to SA4N and SB1N to SB4N are connected to one-side ends of the capacitors CA1N to CA4N and CB1N to CB4N. The second, third, and fourth terminals of each of the switch elements SA1N to SA4N and SB1N to SB4N are connected to the node of an inverted-side input signal NIN, the node of the ground voltage (first reference voltage), and the node of the reference voltage VREF (second reference voltage), respectively. The other-side ends of the capacitors CA1N to CA4N are connected to the node NCN of the inverted input terminal of the comparison circuit 410 (node facing one end of series capacitor CS1N). The other-side ends of the capacitors CB1N to CB4N are connected to the node N1N facing the other end of the series capacitor CS1N.

The capacity ratio among the capacitors CA1P to CA4P and the capacity ratio among the capacitors CB1P to CB4P are each a binary-value ratio (1:2:4:8). The ratio of the capacity of the series capacitor CS1P connected in series to the capacitor CB1P to the capacity of the capacitor CA1P is 1:16. An effective capacity ratio of 1:2:4:8:16:32:64:128 is therefore achieved, allowing D/A-conversion of the 8-bit successive approximation data RDA. The D/A conversion circuit DAC1N similarly has the same capacity ratio and can D/A-convert the 8-bit successive approximation data RDA.

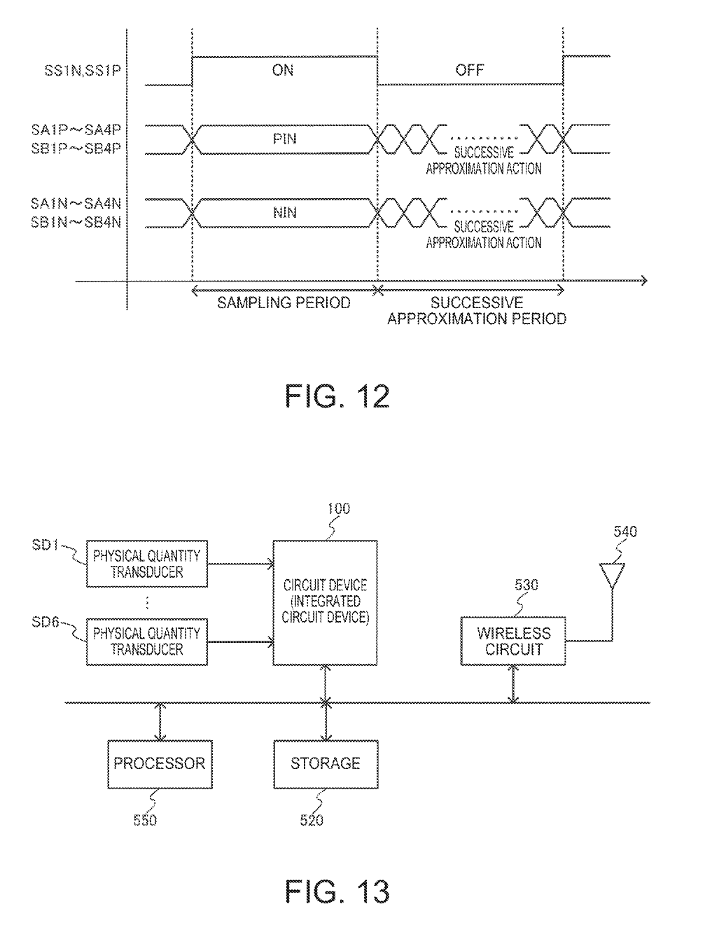

FIG. 12 is a timing chart in accordance with which the A/D conversion circuit in the present embodiment operates. In the sampling period, switch elements SS1P and SS1N are turned on, and the node NCP of the D/A conversion circuit DAC1P and the node NCN of the D/A conversion circuit DAC1N are set at the common voltage VCM. Further, in the sampling period, the first terminal of each of the switch elements SA1P to SA4P and SB1P to SB4P is connected to the second terminal thereof (node of input signal PIN), and the D/A conversion circuit DAC1P samples the input signal PIN. The first terminal of each of the switch elements SA1N to SA4N and SB1N to SB4N is connected to the second terminal thereof (node of input signal NIN), and the D/A conversion circuit DAC1N samples the input signal NIN.

In the successive approximation period, the first terminal of each of the switch elements SA1P to SA4P and SB1P to SB4P is connected to the fourth terminal thereof (node of VREF) when the corresponding bit in the successive approximation data RDA is “1”, whereas connected to the third terminal thereof (node of ground voltage) when the corresponding bit in the successive approximation data RDA is “0”. At this point, the difference between a result of the sampling of the input signal PIN and a result of the D/A conversion of the successive approximation data RDA is outputted to the node NCP. Similarly, the first terminal of each of the switch elements SA1N to SA4N and SB1N to SB4N is connected to the fourth terminal thereof (node of VREF) when the corresponding bit in the successive approximation data RDA is “1”, whereas connected to the third terminal thereof (node of ground voltage) when the corresponding bit in the successive approximation data RDA is “0”. At this point, the difference between a result of the sampling of the input signal NIN and a result of the D/A conversion of the successive approximation data RDA is outputted to the node NCN. The comparison circuit 410 then outputs a comparison result signal CPQ, and the controller 420 updates the register value in the successive approximation register SAR. The comparison action is repeated multiple times corresponding to 8 bits to produce an A/D-converted value.

The period TSAMA in FIG. 5 corresponds to the sampling period in FIG. 12, and the period TCNVA in FIG. 5 corresponds to the successive approximation period.

### 6. Electronic Apparatus, Moving Object

FIG. 13 shows an example of the configuration of an electronic apparatus including the sensor according to the present embodiment. The electronic apparatus includes the physical quantity transducers SD1 to SD6 (sensor elements), the circuit device 100 (integrated circuit device, for example), a processor 550, a storage 520, a wireless circuit 530, and an antenna 540.

The physical quantity transducers SD1 to SD6 detect a variety of physical quantities (such as angular velocity, acceleration, angular acceleration, force, mass, and temperature). Each of the physical quantity transducers SD1 to SD 6 then converts a physical quantity into current (electric charge), voltage, or any other form and outputs the converted physical quantity as a detection signal. The circuit device 100 receives the detection signals from the physical quantity transducers SD1 to SD6, A/D-converts the detection signals, and performs computational processing (signal processing) on the A/D-converted digital data if necessary. The circuit device 100 then outputs the resultant digital data to the processor 550 and other components. The processor 550 performs a variety of digital processing on the digital data. The function of the processor 550 is achieved, for example, by a microcomputer. The storage 520 temporarily stores the digital data and other types of information. The function of the storage 520 is achieved by a RAM and any other type of memory. The wireless circuit 530 modulates or otherwise processes the digital data produced by the circuit device 100 and transmits the modulated or otherwise processed data to an external apparatus (counterpart electronic apparatus) via the antenna 540. Further, data may be received from the external apparatus via the antenna 540 for ID authentication, control of the circuit device 100, and other types of operation may be performed.

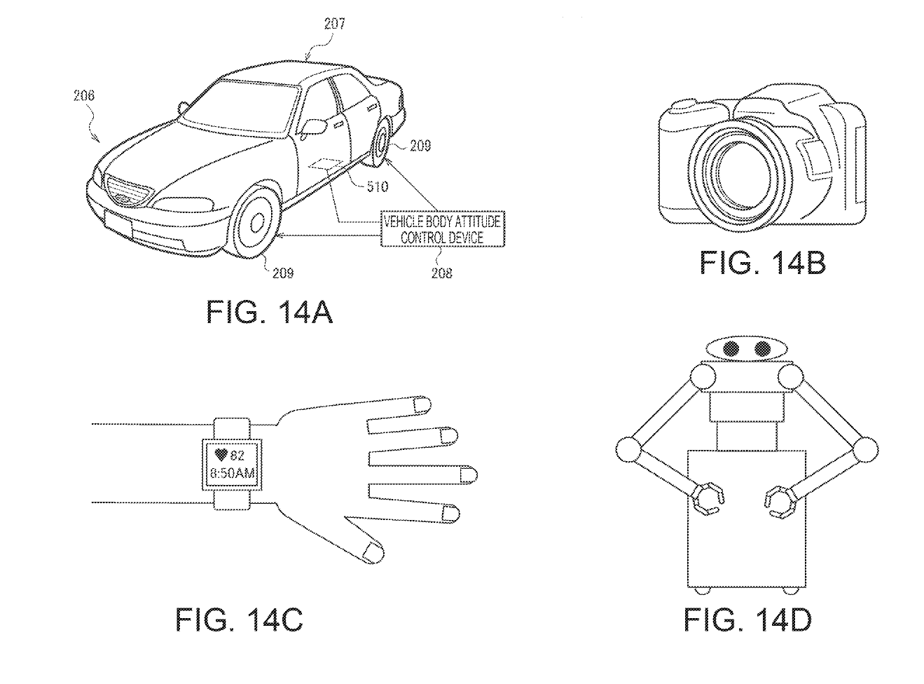

FIG. 14A shows an example of a moving object including the circuit device 100 according to the present embodiment. The circuit device 100 according to the present embodiment can be incorporated, for example, in an automobile, an airplane, a motor cycle, a bicycle, a ship, and a variety of other moving objects. The moving object is an apparatus/device that includes an engine, a motor, or any other drive mechanism, a steering wheel, a rudder, or any other steering mechanism, and a variety of electronic apparatus and travels on the ground, in the sky, or on the sea. FIG. 14A schematically shows an automobile 206 as a specific example of the moving object. The automobile 206 has a gyro sensor 510 (or a combo-sensor further including a physical quantity transducer that detects acceleration) incorporated therein, and the gyro sensor 510 includes a vibrator element and the circuit device 100. The gyro sensor 510 can detect the attitude of a vehicle body 207. A detection signal from the gyro sensor 510 is supplied to a vehicle body attitude control device 208. The vehicle body attitude control device 208 can, for example, control the hardness or softness of the suspension in accordance with the attitude of the vehicle body 207 and control braking of individual wheels 209. The attitude control described above can further be used in a variety of moving objects, such as a bipedal walking robot, an airplane, and a helicopter. To achieve the attitude control, the gyro sensor 510 can be incorporated.

The circuit device 100 according to the present embodiment is applicable to a digital still camera, a biological information detection device (wearable health monitoring apparatus, for example, pulse monitor, pedometer, and activity meter), and a variety of other electronic apparatus, as shown in FIGS. 14B and 14C. For example, in a digital still camera, hand-shake correction and other types of processing using a gyro sensor or an acceleration sensor can be performed. Further, in a biological information detection device, a gyro sensor or an acceleration sensor can be used to detect a user's body motion and the state of the user's motion. Further, the circuit device 100 according to the present embodiment is applicable to a movable section (arm, joint) and a main body of a robot, as shown in FIG. 14D. The robot is conceivably either a moving object (running/walking robot) or an electronic apparatus (non-running/non-walking robot). In the case of a running/walking robot, the circuit device 100 according to the present embodiment can be used, for example, to allow the robot to autonomously run.

The present embodiment has been described above in detail, and a person skilled in the art will readily appreciate that a large number of variations are conceivable to the extent that they do not substantially depart from the novel items and advantageous effects of the invention. Such variations are all therefore assumed to fall within the scope of the invention. For example, a term described at least once in the specification or the drawings along with a different term having a boarder meaning or the same meaning can be replaced with the different term anywhere in the specification or the drawings. Further, any combination of the present embodiment and the variations fall within the scope of the invention. Moreover, the configuration, operation, and other factors of each of the physical quantity transducers, the circuit device, the sensor, the electronic apparatus, and the moving object are not limited to those described in the present embodiment, and a variety of changes can be made thereto.

The entire disclosure of Japanese Patent Application No. 2015-050550, filed Mar. 13, 2015 is expressly incorporated by reference herein.

What is claimed is:

1. A circuit device comprising:
a multiplexer that selects an input signal from first to n-th input signals (n is an integer greater than or equal to 2) inputted to first to n-th input nodes in a time division manner and outputs the selected input signal to an output node;
an A/D conversion circuit that receives the first to n-th input signals outputted from the multiplexer to the output node in a time division manner and A/D-converts the received first to n-th input signals in a time division manner; and
a buffer circuit provided between an i-th input node (i is an integer greater than or equal to 1 but smaller than or equal to n) among the first to n-th input nodes and the output node of the multiplexer,
wherein the buffer circuit buffers the i-th input signal among the first to n-th input signals and outputs the buffered signal to the output node of the multiplexer in a first period,
the multiplexer selects the i-th input signal and outputs the selected signal to the output node in a second period, and
end timing of the second period comes after end timing of the first period.

2. The circuit device according to claim 1,
wherein the A/D conversion circuit samples the i-th input signal after the end timing of the first period but before the end timing of the second period.

3. The circuit device according to claim 1,
wherein start timing of the second period comes after start timing of the first period.

4. The circuit device according to claim 2,
wherein start timing of the second period comes after start timing of the first period.

5. The circuit device according to claim 1,
wherein the buffer circuit includes
an amplifier circuit that amplifies the i-th input signal, and
a switch element provided between an output of the amplifier circuit and the output node of the multiplexer, and
the switch element is turned on in the first period.

6. The circuit device according to claim 2,
wherein the buffer circuit includes
an amplifier circuit that amplifies the i-th input signal, and
a switch element provided between an output of the amplifier circuit and the output node of the multiplexer, and
the switch element is turned on in the first period.

7. The circuit device according to claim 3,
wherein the buffer circuit includes
an amplifier circuit that amplifies the i-th input signal, and
a switch element provided between an output of the amplifier circuit and the output node of the multiplexer, and
the switch element is turned on in the first period.

8. The circuit device according to claim 1, further comprising
a second buffer circuit provided between an (i+1)-th input node (i is smaller than or equal to n−1) among the first to n-th input nodes and the output node of the multiplexer,
wherein the second buffer circuit buffers an (i+1)-th input signal among the first to n-th input signals and outputs the buffered signal to the output node in a third period,
the multiplexer selects the (i+1)-th input signal and outputs the selected signal to the output node in a fourth period, and
end timing of the fourth period is set at a point after end timing of the third period.

9. The circuit device according to claim 2, further comprising
a second buffer circuit provided between an (i+1)-th input node (i is smaller than or equal to n−1) among the first to n-th input nodes and the output node of the multiplexer,
wherein the second buffer circuit buffers an (i+1)-th input signal among the first to n-th input signals and outputs the buffered signal to the output node in a third period,
the multiplexer selects the (i+1)-th input signal and outputs the selected signal to the output node in a fourth period, and
end timing of the fourth period is set at a point after end timing of the third period.

10. The circuit device according to claim 3, further comprising
a second buffer circuit provided between an (i+1)-th input node (i is smaller than or equal to n−1) among the first to n-th input nodes and the output node of the multiplexer,
wherein the second buffer circuit buffers an (i+1)-th input signal among the first to n-th input signals and outputs the buffered signal to the output node in a third period,
the multiplexer selects the (i+1)-th input signal and outputs the selected signal to the output node in a fourth period, and
end timing of the fourth period is set at a point after end timing of the third period.

11. The circuit device according to claim 8,
wherein start timing of the third period is set at a point after the end timing of the second period.

12. The circuit device according to claim 1, further comprising
a passive low-pass filter,
wherein the i-th input signal is an output signal from the passive low-pass filter.

13. The circuit device according to claim 12, further comprising
a detection circuit to which a detection signal from a physical quantity transducer is inputted,
wherein the i-th input signal is an output signal outputted by the detection circuit and inputted via the passive low-pass filter.

14. The circuit device according to claim 13,
wherein the physical quantity transducer is an angular velocity sensor.

15. The circuit device according to claim 13,
wherein the physical quantity transducer is an acceleration sensor.

16. The circuit device according to claim 13,
wherein the i-th input signal is formed of differential signals, and the output node of the multiplexer is formed of differential nodes, and
the A/D conversion circuit A/D-converts the i-th input signal outputted to the differential nodes.

17. The circuit device according to claim 13,
wherein the detection circuit includes a synchronization detection circuit.

18. The circuit device according to claim 17,
wherein the detection circuit includes
an amplification circuit provided in a stage upstream of the synchronization detection circuit, and
an electric charge/voltage conversion circuit provided in a stage upstream of the amplification circuit.

19. An electronic apparatus comprising the circuit device according to claim 1.

20. A moving object comprising the circuit device according to claim 1.
